(19) United States
(12) Patent Application Publication
(10) Pub. No.: US 2015/0083045 A1
(43) Pub. Date: Mar. 26, 2015

(54) MASK FIXING DEVICE AND DEPOSITION APPARATUS HAVING THE SAME

(71) Applicant: Samsung Display Co., Ltd., Yongin-City (KR)

(72) Inventors: Sukbeom YOU, Anyang-si (KR); Hyungmin Kim, Seongnam-si (KR)

(73) Assignee: Samsung Display Co., Ltd., Yongin-City (KR)

(21) Appl. No.: 14/276,874

(22) Filed: May 13, 2014

(30) Foreign Application Priority Data
Sep. 25, 2013 (KR) 10-2013-0114024

(51) Int. Cl. H01L 51/56

(52) U.S. Cl. CPC H01L 51/56
USPC 118/721; 118/505

(57) ABSTRACT

A mask fixing device is disclosed. In one aspect, the mask fixing device includes a plate and a magnetic assembly. The magnetic assembly faces a mask such that a substrate is interposed therebetween and generates a magnetic force to fix the mask to the substrate. The plate holds the magnetic assembly and faces the substrate. The magnetic assembly includes a plurality of first and second magnetic members respectively having first and second magnetic poles. The first magnetic members and the second magnetic members are alternately arranged.

### CROSS-REFERENCE TO RELATED APPLICATIONS

This U.S. non-provisional patent application claims priority under 35 U.S.C. §119 of Korean Patent Application No. 10-2013-0114024, filed on Sep. 25, 2013, the contents of which are hereby incorporated by reference in its entirety.

### BACKGROUND

1. Field

The described technology generally relates to a mask fixing device and a deposition apparatus including the same.

2. Description of the Related Technology

Organic light-emitting diode (OLED) displays are increasing in popularity due to their favorable qualities such as low power consumption and superior display quality when compared to liquid crystal displays (LCDs). OLED displays have an OLED formed in each pixel area thereof. Each OLED includes a cathode, an anode, and an organic light-emitting layer interposed between them.

Generally, deposition or thermal transfer is used in forming the organic light-emitting layer on a substrate. When a deposition method is used to form the organic light-emitting layer, a mask is fixed to the substrate in order to pattern the organic light-emitting layer on the substrate.

### SUMMARY OF CERTAIN INVENTIVE ASPECTS

One inventive aspect is a mask fixing device capable of stably fixing a mask to a substrate.

Another aspect is a mask fixing device including a plate and a magnetic assembly. The magnetic assembly is fixed to the plate. The magnetic assembly includes first magnetic members each having a first magnetic pole contacting the plate and extending in a first direction and second magnetic members each having a second magnetic pole contacting with the plate and extending in the first direction. The first and second magnetic poles have different polarities. The magnetic members are arranged such that a pair of first magnetic members and a pair of second magnetic members are alternately arranged in a second direction crossing the first direction.

Another aspect is a deposition apparatus including a chamber, a deposition source, and a mask fixing device. The deposition source is disposed in the chamber to provide a deposition material to a substrate and the mask fixing device is disposed in the chamber to fix a mask to the substrate. The mask fixing device includes a plate and a magnetic assembly. The magnetic assembly applies a magnetic force to fix the mask to the substrate. The substrate is interposed between the magnetic assembly and the mask. The magnetic assembly is fixed to the plate. The magnetic assembly includes first magnetic members each having a first magnetic pole contacting the plate and extending in a first direction and second magnetic members each having a second magnetic pole contacting the plate and extending in the first direction. The first and second magnetic poles have different polarities. The magnetic members are arranged such that at least two neighboringfirst magnetic members and at least two neighboring second magnetic members are alternately and repeatedly arranged in a second direction crossing the first direction.

Another aspect is a mask fixing device that fixes a mask to a substrate for a display device including a magnetic assembly. The magnetic assembly includes first magnetic members and second magnetic members. The first and second magnetic members each respectively having first and second magnetic poles and configured to contact the substrate, wherein the first and second magnetic members are configured to apply a magnetic force to the mask to fix the mask to the substrate, wherein the substrate is interposed between and contact the magnetic assembly and the mask, wherein the first and second magnetic poles have different polarities, and wherein first magnetic members and the second magnetic members are alternately arranged.

The mask fixing device further includes a plate holding at least a part of the magnetic assembly, wherein the plate does not contact the substrate. Recesses are defined in a surface of the plate facing the magnetic assembly and at least a part of the magnetic assembly is accommodated in the recesses.

According to at least one embodiment, the magnetic force applied to the mask is substantially uniform due to the configuration of a magnetic assembly included in the mask fixing device. Therefore, the mask may be fixed to the substrate using the magnetic assembly and the mask may be prevented from being detached from the substrate. In addition, when the mask fixing device is employed in the deposition apparatus, the quality of the deposition pattern formed on the substrate using the deposition material may be improved.

### BRIEF DESCRIPTION OF THE DRAWINGS

FIG. 1 is an exploded perspective view showing a mask fixing device according to an exemplary embodiment.

FIG. 2 is a cross-sectional view taken along line I-I′ of FIG. 1.

FIG. 3A is a cross-sectional view showing the fixing a mask to a substrate according to an embodiment.

FIG. 3B is a graph showing the magnetic force intensity according to positions on a mask.

FIG. 4 is a plan view showing a mask fixing device according to another exemplary embodiment.

FIG. 5 is a cross-sectional view showing a deposition apparatus according to an exemplary embodiment.

### DETAILED DESCRIPTION OF CERTAIN INVENTIVE EMBODIMENTS

One method of fixing a mask to a substrate includes mechanically fixing both side portions of the mask to the substrate using a tool, e.g., pin, clip, etc. Another method includes magnetically fixing the mask to the substrate using magnetic force.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the described technology.

Spatially relative terms, such as “beneath”, “below”, “lower”, “above”, ^{“}upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein are to be interpreted accordingly.

The terminology used herein is for the purpose of describing particular embodiments only and is not intended to be limiting of the described technology. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the described technology belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the described technology will be explained in detail with reference to the accompanying drawings.

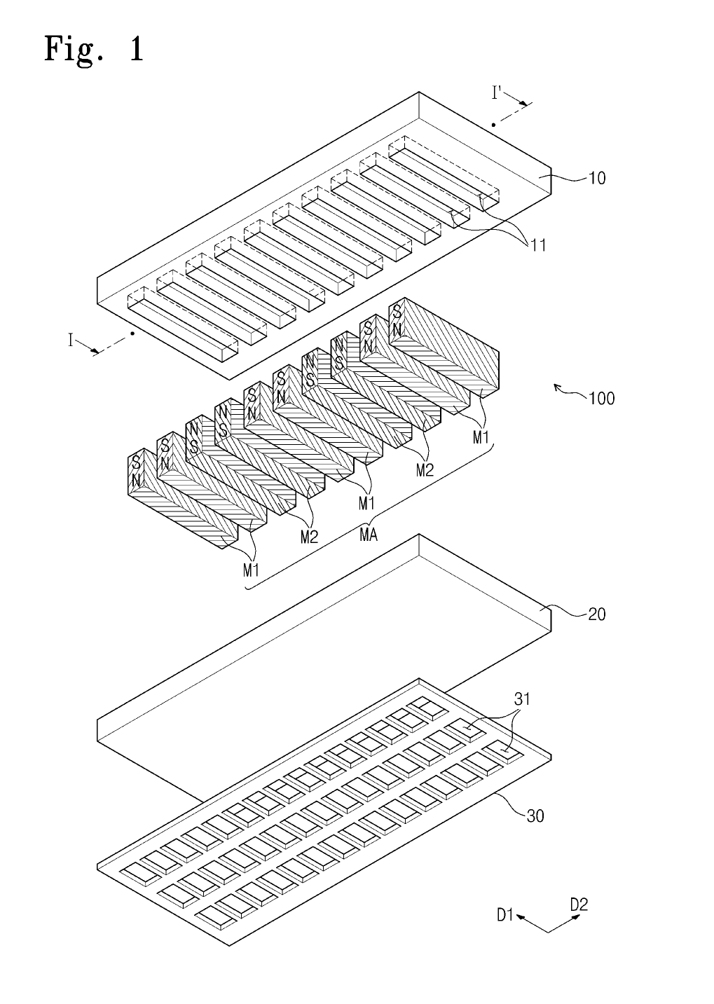

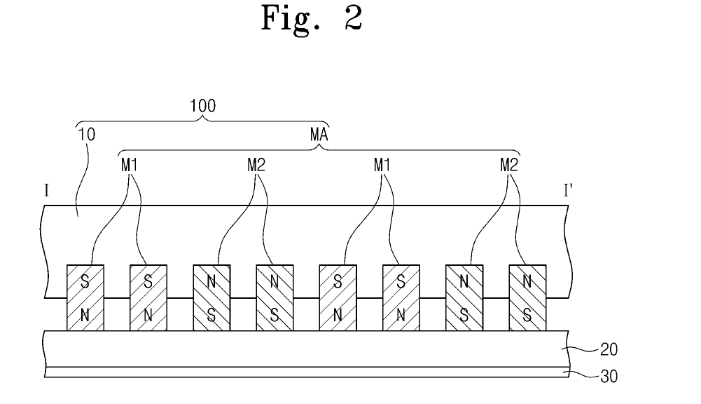

FIG. 1 is an exploded perspective view showing a mask fixing device according to an exemplary embodiment and FIG. 2 is a cross-sectional view taken along line I-I′ of FIG. 1.

Referring to FIGS. 1 and 2, a mask fixing device 100 includes a plate 10 and a magnetic assembly MA.

The plate 10 is coupled to the magnetic assembly MA to fix the magnetic assembly MA to the plate 10. In the present exemplary embodiment, the plate 10 includes recesses 11 formed on a surface thereof, which face the magnetic assembly MA. The magnetic assembly MA is accommodated in the recesses 11, and thus, the magnetic assembly MA is fixed to the plate 10.

The magnetic assembly MA includes first magnetic members M1 and second magnetic members M2. A first magnetic pole of each of the first magnetic members M1 and a second magnetic pole of each of the second magnetic members M2 contact the plate 10. The first and second magnetic poles have different polarities. According to some embodiments, the first magnetic pole is a south (S) pole and the second magnetic pole is a north (N) pole, however, the described technology is not limited thereto or thereby. That is, according to other embodiments, the first and second magnetic poles are N and S poles, respectively.

The first and second magnetic members M1 and M2 are arranged on the plate 10. In detail, two first magnetic members M1 are alternately arranged with two second magnetic members M2 on the plate 10. That is, two first magnetic members are sequentially placed on the plate 10, two second magnetic members are sequentially placed after the two first magnetic members, a second set of two first magnetic members are sequentially placed after the two second magnetic members, and then a second set of two second magnetic members are sequentially placed after the “second set of two first magnetic members”.

In the present exemplary embodiment, each of the first and second magnetic members M1 and M2 has a bar shape extending in a first direction D1. In addition, the first and second magnetic members M1 and M2 are arranged on the plate 10 in a second direction D2 substantially perpendicular to the first direction D1.

The mask fixing device 100 is disposed to face a mask 30 with a substrate 20 interposed between the mask fixing device 100 and the mask 30. The mask 30 is provided with openings 31 formed therethrough to form a pattern on the substrate 20. The mask fixing device 100 generates a magnetic force which is applied to the mask 30, and thus, the mask 30 is fixed to the substrate 20 by the magnetic force.

In the present exemplary embodiment, the first and second magnetic members M1 and M2 are permanent magnets, however, the described technology is not limited thereto or thereby. That is, the first and second magnetic members M1 and M2 may be electromagnets.

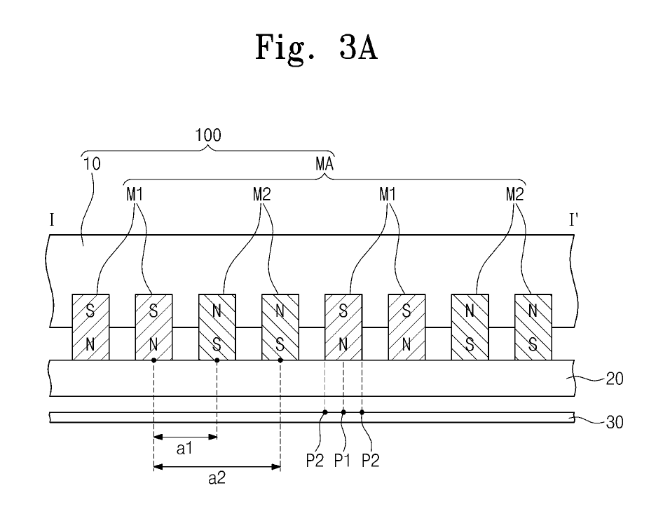

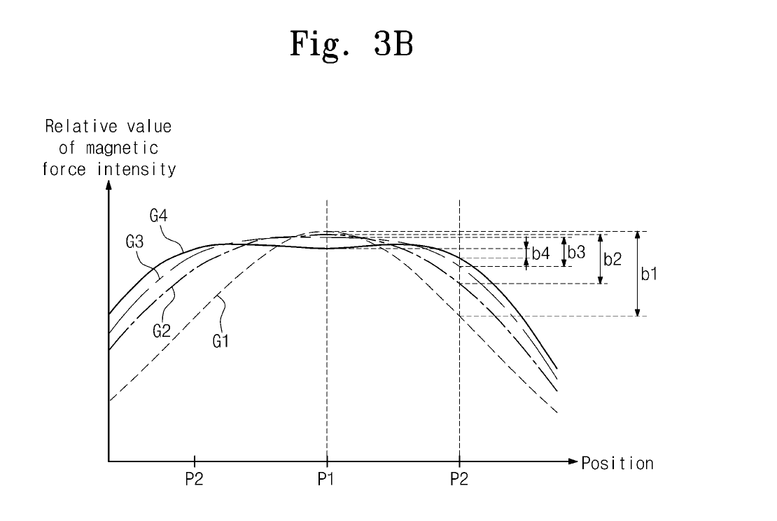

FIGS. 3A and 3B are views illustrating the fixing the mask 30 to the substrate 20 according to an embodiment. In detail, FIG. 3A shows a cross-sectional view taken along line I-I′ of FIG. 1 and FIG. 3B is a graph showing the relative intensities of the magnetic force according to positions on the mask 30.

Referring to FIG. 3A, the two first magnetic members M1 are alternately and repeatedly arranged with the two second magnetic members M2 on the plate 10. One of the first magnetic members M1 is adjacent to a pair of second magnetic members M2. Hereinafter, the distance between a center of the first magnetic member and a center of the first of the pair of second magnetic members which is adjacent to the first magnetic member is referred to as a first distance or first pitch a1. The distance between the center of the first magnetic member and a center of the second of the pair of second magnetic members is referred to as a second distance or second pitch a2. The first magnetic member and the second of the pair of second magnetic members are arranged with the first of the pair of second magnetic members interposed therebetween.

The first pitch a1 has a value in the range of about 40% to about 60% of the second pitch a2. For instance, when the second pitch a2 is about 22 mm, the first pitch a1 is between about 9 mm to about 13 mm.

In addition, the position of the mask 30 facing the center of each of the first magnetic members M1 or the center of each of the second magnetic members M2 is referred to as a first point (or a first portion) P1. The position of the mask 30 facing the edge of each of the first magnetic members M1 or the edge of each of the second magnetic members M2 is referred to as a second point (or a second portion) P2. According to at least one embodiment, the intensities of the magnetic force generated by the magnetic assembly MA and applied to each of the first and second points P1 and P2 may be substantially uniform. This will be described in detail with reference to FIG. 3B.

In FIGS. 3A and 3B, first, second, third, and fourth graphs G1, G2, G3, and G4 illustrate a comparative example and embodied examples of the described technology. Each of the first to fourth graphs G1 to G4 represents the relative intensities of the magnetic force according to the positions on the surface of the mask 30. In addition, each of the first to fourth graphs G1 to G4 represents normalized values obtained by dividing the value of the intensity of the magnetic force measured at each position on the surface of the mask 30 by the maximum value of the measured magnetic force. The surface of the mask 30 referred to in the graphs is the surface of the mask 30 facing the substrate 20 and disposed closer to the substrate 20.

The first graph G1 represents the relative intensities of the magnetic force according to the positions on the surface of the mask 30 in the comparative example. In the magnetic assembly according to the comparative example, a first magnetic member and a second magnetic member are alternately and repeatedly arranged.

Each of the second to fourth graphs G2 to G4 represents the relative intensities of the magnetic force according to embodied examples. In detail, the second graph G2 represents the relative intensities of the magnetic force for an embodiment where the first pitch a1 is about 13 mm and the second pitch a2 is about 22 mm. The third graph G3 represents the relative intensities of the magnetic force for an embodiment where the first pitch a1 is about 11 mm and the second pitch a2 is about 22 mm, and the fourth graph G4 represents the relative intensities of the magnetic force for an embodiment where the first pitch a1 is about 9 mm and the second pitch a2 is about 22 mm.

In the first graph G1, the difference between the intensities of the magnetic forces applied to the first and second points P1 and P2 is referred to as a first value b1. Similarly, the difference between the intensities of the magnetic forces applied to the first and second points P2 in the second graph G2 is referred to as a second value b2. As illustrated in FIG. 3B, the second value b2 is less than the first value b1.

Similarly, when the difference between the intensities of the magnetic forces applied to the first and second points P1 and P2 in the third graph G3 is referred to as a third value b3. Here, the third value b3 is less than the first value b1. In addition, the difference between the intensities of the magnetic forces applied to the first and second points P1 and P2 in the fourth graph G4 is referred to as a fourth value b4. The fourth value b4 is also less than the first value b1.

As described above, the difference between the intensities of the magnetic forces applied to the first and second points P1 and P2 is reduced in the embodied examples when compared with the comparative example. Therefore, when the magnetic assembly MA has the above-mentioned structure according to the present exemplary embodiment, the intensity of the magnetic force applied to the mask 30 may be more uniform than that of the comparative example. In addition, since the intensity of the magnetic force applied to the second point P2 is comparatively high, the distribution of magnetic field applied to the mask 30 is comparatively broad.

In other words, the magnetic force applied to each of the first and second points P1 and P2 is determined based on the first and second pitchs a1 and a2. Consequently, the uniformity of the magnetic force applied across the width of each magnetic member M1 or M2 can be selected by varying the first and second pitchs a1 and a2.

According to the comparative example, the intensity of the magnetic force applied to the mask 30 is non-uniform, and thus, the mask 30 may be deformed. According to the embodied examples, however, since the intensity of the magnetic force applied to the mask 30 is substantially uniform, the mask 30 may be prevented from being deformed. In addition, when the intensity of the magnetic force applied to the mask 30 is substantially uniform, the force acting between the mask 30 and the substrate 20, which is required to adhere the mask 30 to the substrate, is substantially uniform for a wide range of positions on the surface of the mask 30. Thus, the mask 30 may be prevented from being detached from the substrate 20.

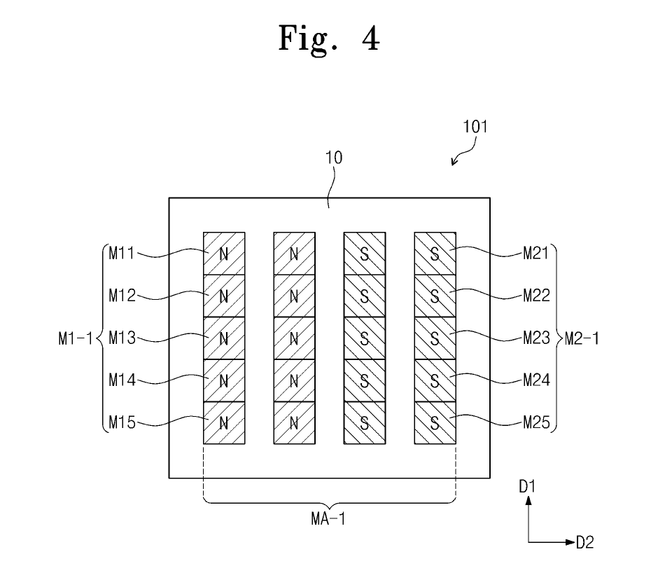

FIG. 4 is a plan view showing a mask fixing device according to another exemplary embodiment. In FIG. 4, the same reference numerals denote the same elements in FIGS. 1 to 3, and thus, detailed descriptions of the same elements will be omitted.

Referring to FIG. 4, the mask fixing device 101 includes a plate and a magnetic assembly MA-1.

The magnetic assembly MA-1 includes first magnetic members M1-1 and second magnetic members M2-1. The first magnetic pole of each of the first magnetic members M1-1 and the second magnetic pole of each of the second magnetic members M2-1 contact the plate 10. The first and second magnetic poles have different polarities.

In the present exemplary embodiment, each of the first magnetic members M1-1 includes first, second, third, fourth, and fifth magnets M11, M12, M13, M14, and M15, which are arranged in a first direction D1 and contact each other. In addition, each of the second magnetic members M1-2 includes sixth, seventh, eighth, ninth, and tenth magnets M21, M22, M23, M24, and M25, which are arranged in the first direction D1 and contact each other. In the present embodiment, each of the first and second magnetic members M1-1 and M2-1 include five magnets, however, the described technology is not limited to five magnets in each magnetic member.

As described above, when each of the first and second magnetic members M1-1 and M2-1 include a plurality of magnets arranged in the first direction D1, the strength of the magnetic assembly MA-1 is improved against external stress.

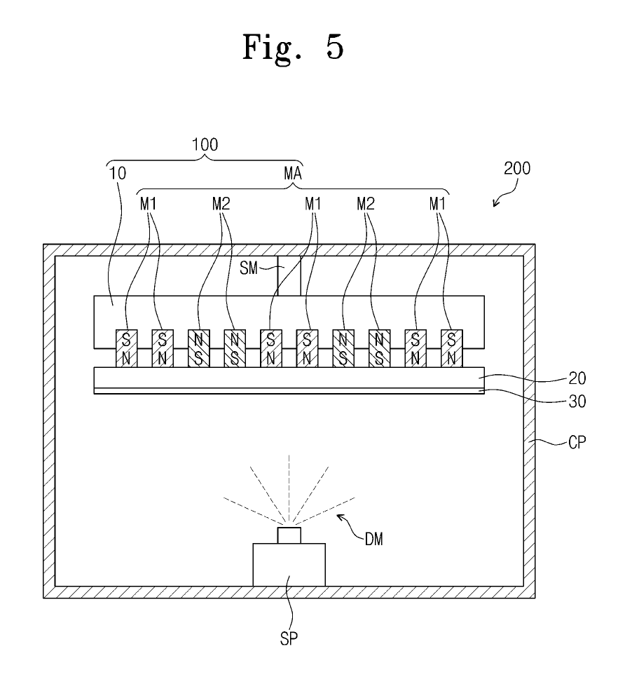

FIG. 5 is a cross-sectional view showing a deposition apparatus according to an exemplary embodiment. In FIG. 5, the same reference numerals denote the same elements in FIGS. 1 to 3, and thus, detailed descriptions of the same elements will be omitted.

Referring to FIG. 5, a deposition apparatus 200 includes a chamber CP, a deposition source SP, and a mask fixing device 100.

The chamber CP accommodates the deposition source SP, the mask fixing device 100, a mask 30, and a substrate 20. When a deposition process is performed on the substrate 20, the inside of the chamber CP is brought to a vacuum. To maintain the vacuum in the chamber CP, a vacuum pump (not shown) may be connected to the chamber CP.

The deposition apparatus 200 may further include a holder SM disposed in the chamber CP to hold the substrate 20. The holder SM may be rotated during the deposition process to substantially uniformly form a deposition pattern on the substrate 20.

The substrate 20 may be a flat panel member configured to serve as a part of display panel. In the present exemplary embodiment, the substrate 20 may be a glass substrate. Hereinafter, the substrate 20 will be described as a display substrate for an OLED display.

The deposition source SP evaporates a deposition material DM and the evaporated deposition material DM is provided to the substrate 20. The deposition source SP includes a container (not shown) accommodating the deposition material DM and a heater (not shown) that heats the deposition material DM.

The deposition material DM is deposited on the substrate through openings in the mask 30, and thus, a deposition pattern formed of the deposition material DM may be formed on the substrate 20. In the present exemplary embodiment, the deposition pattern may be an organic light-emitting layer.

As described with reference to FIGS. 3A and 3B, the mask fixing device 100 allows a magnetic force to be applied to the mask 30 with a substantially uniform intensity. In this case, the mask 30 may be adhered to a lower surface of the substrate 20 without being deformed, and thus, the mask 30 can accurately define areas in which the deposition material DM is deposited. As a result, the yield of the process of patterning the organic light-emitting layer formed of the deposition material DM may be improved.

Although certain embodiments have been described, it is understood that the present invention should not be limited to these embodiments but various changes and modifications can be made by one ordinary skilled in the art within the spirit and scope of the present invention as hereinafter claimed.

What is claimed is:

1. A mask fixing device that fixes a mask to a substrate for a flat panel display, comprising:
a magnetic assembly configured to apply a magnetic force to the mask so as to fix the mask to the substrate, wherein the substrate is configured to be interposed between and contact one end of the magnetic assembly and the mask; and
a plate holding at least another opposing end of the magnetic assembly and configured to face the substrate,
wherein the magnetic assembly comprises:
a plurality of first magnetic members each having a first magnetic pole facing the plate; and
a plurality of second magnetic members each having a second magnetic pole facing the plate, wherein the second magnetic pole is different from the first magnetic pole,
wherein at least two neighboring first magnetic members are alternately and repeatedly arranged with at least two neighboring second magnetic members.

2. The mask fixing device of claim 1, wherein each of the first and second magnetic members has a bar shape.

3. The mask fixing device of claim 1, wherein each of the first and second magnetic members comprises a plurality of magnets contacting each other.

4. The mask fixing device of claim 1, wherein recesses are defined in a surface of the plate facing the magnetic assembly and wherein at least a part of the magnetic assembly is accommodated in the recesses.

5. The mask fixing device of claim 1, wherein at least two first adjacent ones of the first and second magnetic members are spaced apart from each other such that the distribution of the magnetic field applied to the mask is substantially uniform over the width of the magnetic members and wherein the two first adjacent magnetic members have different polarities.

6. The mask fixing device of claim 5, wherein the mask includes a first portion facing the center of each of the first magnetic members and a second portion facing an edge of each of the first magnetic members and wherein the intensity of the magnetic force applied to each of the first and second portions is substantially the same.

7. The mask fixing device of claim 6, wherein a first pitch is defined as the distance between center portions of the two first adjacent magnetic members, wherein a second pitch is defined as the distance between a center portion of one of the two first adjacent magnetic members and a center portion of a second adjacent member adjacent to and having the same polarity as the other adjacent member, and wherein the first pitch is about 40% to about 60% of the second pitch.

8. The mask fixing device of claim 7, wherein the first pitch is between about 9 mm to about 13 mm and the second pitch is about 22 mm.

9. A deposition apparatus for a display device, comprising:
a chamber;
a deposition source disposed in the chamber and configured to provide a deposition material to the substrate;
a mask fixing device disposed in the chamber to fix a mask to the substrate, the mask fixing device comprising:
a magnetic assembly configured to apply a magnetic force to the mask so as to fix the mask to the substrate, wherein the substrate is configured to be interposed between and contact one end of the magnetic assembly and the mask; and
a plate holding at least another opposing end of the magnetic assembly,
wherein the magnetic assembly comprises:
a plurality of first magnetic members each having a first magnetic pole facing the plate; and
a plurality of second magnetic members each having a second magnetic pole facing the plate, wherein the second magnetic pole is different from the first magnetic pole,
wherein at least two neighboring first magnetic members are alternately and repeatedly arranged with at least two neighboring second magnetic members.

10. The deposition apparatus of claim 9, wherein each of the first and second magnetic members has a bar shape.

11. The deposition apparatus of claim 9, wherein each of the first and second magnetic members comprises a plurality of magnets contacting each other.

12. The deposition apparatus of claim 9, wherein recesses are defined in a surface of the plate facing the magnetic assembly and wherein at least a part of the magnetic assembly is accommodated in the recesses.

13. The deposition apparatus of claim 9, wherein at least two first adjacent ones of the first and second magnetic members are spaced apart from each other such that the distribution of the magnetic field applied to the mask is substantially uniform over the width of the magnetic members and wherein the two first adjacent magnetic members have different polarities.

14. The deposition apparatus of claim 13, wherein the mask includes a first portion facing the center of each of the first magnetic members and a second portion facing an edge of each of the first magnetic members and wherein the intensity of the magnetic force applied to each of the first and second portions is substantially the same.

15. The deposition apparatus of claim 14, wherein a first pitch is defined as the distance between center portions of the two first adjacent magnetic members, wherein a second pitch is defined as the distance between a center portion of one of the two first adjacent magnetic members and center portion of a second adjacent member adjacent to and having the same polarity as the other adjacent member, and wherein the first pitch is about 40% to about 60% of the second pitch.

16. The deposition apparatus of claim 15, wherein the first pitch is between about 9 mm to about 13 mm and the second pitch is about 22 mm.

17. The deposition apparatus of claim 9, wherein the deposition material is an organic material.

18. A mask fixing device that fixes a mask to a substrate for a display device, comprising:
a magnetic assembly comprising first magnetic members and second magnetic members;
wherein the first and second magnetic members each respectively having first and second magnetic poles configured to face and contact the substrate,
wherein the first magnetic members comprise a plurality of first groups of magnetic members spaced apart from each other, wherein each first group comprises at least two first magnetic members neighboring each other,
wherein the second magnetic members comprise a plurality of second groups of magnetic members spaced apart from each other, wherein each second group comprises at least two second magnetic members neighboring each other,
wherein the first and second magnetic members are configured to apply a magnetic force to the mask to fix the mask to the substrate,
wherein the substrate is interposed between and contacts the magnetic assembly and the mask,
wherein the first and second magnetic poles have different polarities, and
wherein the first groups of magnetic members and the second groups of magnetic members are alternately arranged.

19. The mask of claim 18, further comprising a plate holding at least a part of the magnetic assembly, wherein the plate does not contact the substrate.

20. The mask of claim 18, wherein recesses are defined in a surface of the plate facing the magnetic assembly and wherein at least a part of the magnetic assembly is accommodated in the recesses.
